(19) United States
(12) Patent Application Publication
(10) Pub. No.: US 2026/0123160 A1
(43) Pub. Date: Apr. 30, 2026

(54) ELECTRONIC DEVICE, DISPLAY PANEL AND PHOTOCURING METHOD

(71) Applicant: Tianma Advanced Display Technology Institute (Xiamen) Co.,Ltd., Xiamen (CN)

(72) Inventor: Yunyuan ZHANG, Xiamen (CN)

(21) Appl. No.: 19/059,343

(22) Filed: Feb. 21, 2025

(30) Foreign Application Priority Data
Oct. 31, 2024 (CN) 202411547285.0

(51) Int. Cl. H10H 29/855; H10H 29/01; H10H 29/37

(52) U.S. Cl. CPC H10H 29/8552; H10H 29/0363; H10H 29/37

(57) ABSTRACT

The present disclosure discloses an electronic device, a display panel, and a photocuring method. The display panel includes an array substrate, where the array substrate includes a transparent substrate, a circuit layer disposed on one side of the transparent substrate, and a plurality of light emitting elements fixed on the circuit layer, the light emitting elements being electrically connected to pixel circuits in the circuit layer; and a black glue layer, where the black glue layer includes a first part disposed between the light emitting elements and a second part of disposed between a bottom of a light emitting element and the circuit layer. The circuit layer has a preset light-through path, and the light-through path enables light for photocuring the black glue layer to be irradiated from the transparent substrate to the second part of the black glue layer.

### CROSS-REFERENCE TO RELATED DISCLOSURE

This application claims priority of Chinese Patent Application No. 202411547285.0 filed on Oct. 31, 2024, the entire content of which is hereby incorporated by reference.

### TECHNICAL FIELD

This application relates to the technical field of display devices, and more specifically, to an electronic device, a display panel, and a photocuring method.

### BACKGROUND

For a display panel that uses light emitting elements welded and fixed on an array substrate as a display panel for image display, a black glue layer needs to be provided on the array substrate to prevent light crosstalk between different light emitting elements. In the existing technologies, the black glue layer between the bottom of the light emitting elements and the array substrate cannot be effectively cured, which affects the reliability and stability of the display panel.

### SUMMARY

In view of the foregoing, the present disclosure provides an electronic device, a display panel and a photocuring method.

One aspect of the present disclosure provides a display panel, including: an array substrate, where the array substrate includes a transparent substrate, a circuit layer disposed on a surface of the transparent substrate, and a plurality of light emitting elements fixed on the circuit layer, the light emitting elements being electrically connected to pixel circuits in the circuit layer; and a black glue layer, where the black glue layer includes a first part disposed between the light emitting elements and a second part disposed between a bottom of a light emitting element and the circuit layer. The circuit layer has a preset light-through path, and the light-through path enables light for photocuring the black glue layer to be irradiated from the transparent substrate to the second part of the black glue layer.

Another aspect of the present disclosure provides an electronic device including a display panel, where the display panel includes: an array substrate, where the array substrate includes a transparent substrate, a circuit layer disposed on a surface of the transparent substrate, and a plurality of light emitting elements fixed on the circuit layer, the light emitting elements being electrically connected to pixel circuits in the circuit layer; and a black glue layer, where the black glue layer includes a first part disposed between the light emitting elements and a second part disposed between a bottom of a light emitting element and the circuit layer. The circuit layer has a preset light-through path, and the light-through path enables light for photocuring the black glue layer to be irradiated from the transparent substrate to the second part of the black glue layer.

Another aspect of the present disclosure provides a photocuring method for the aforementioned display panel, where the method includes: irradiating with UV light from a side of the light emitting element to photo-cure at least the first part of the black glue layer; and irradiating with UV light from a side of the transparent substrate away from the circuit layer, through the light-through path, so as to photo-cure at least the second part of the black glue layer.

Other features of the present disclosure and advantages thereof will become apparent from the following detailed description of exemplary embodiments of the present disclosure with reference to the accompanying drawings.

### BRIEF DESCRIPTION OF THE DRAWINGS

In order to more clearly illustrate the technical solutions in the embodiments of the present disclosure or the related technologies, the drawings essential for understanding the embodiments or the description of the existing technologies will be briefly introduced below. Apparently, the drawings described below are merely some embodiments of the present disclosure. For a person skilled in the art, other drawings may be obtained based on the provided drawings without making creative efforts.

The structures, proportions, sizes, etc., illustrated in the drawings of this specification are merely used to match the contents disclosed in the specification so as to facilitate understanding and reading by a person skilled in the art, but are not used to limit the conditions under which the disclosure may be implemented. Any structural modification, change in proportion or adjustment of size, without affecting the effects and purposes that may be achieved by the disclosure, should still fall within the scope of the technical contents disclosed in the disclosure.

FIG. 1 is a schematic diagram showing the principle of photocuring a conventional display panel;

FIG. 2 illustrates the transmittance curves of Micro LED chips to the light of different wavelengths;

FIG. 3 is a schematic structural diagram of a display panel, in accordance with an embodiment of the present disclosure;

FIG. 4 is a schematic diagram of a principle of configuring a light-through path, in accordance with an embodiment of the present disclosure;

FIG. 5 is a schematic diagram of another principle of configuring a light-through path, in accordance with an embodiment of the present disclosure;

FIG. 6 is a partially enlarged schematic diagram of the display panel shown in FIG. 5 before a black glue layer is laid;

FIG. 7 is another partially enlarged schematic diagram of the display panel shown in FIG. 5 before a black glue layer is laid;

FIG. 8 is another partially enlarged schematic diagram of the display panel shown in FIG. 5 before a black glue layer is laid;

FIG. 9 is another partially enlarged schematic diagram of the display panel shown in FIG. 5 before a black glue layer is laid;

FIG. 10 is another partially enlarged schematic diagram of the display panel shown in FIG. 5 before a black glue layer is laid;

FIG. 11 is another partially enlarged schematic diagram of the display panel shown in FIG. 5 before a black glue layer is laid;

FIG. 12 is a top view of the N-th metal layer in the array substrate;

FIG. 13 is a top view of the (N-1)-th metal layer in the array substrate;

FIG. 14 is a schematic structural diagram of a pixel circuit, in accordance with an embodiment of the present disclosure;

FIG. 15 is a schematic structural diagram of an electronic device, in accordance with an embodiment of the present disclosure; and

FIG. 16 is a flow chart of a display panel photocuring method, in accordance with an embodiment of the present disclosure.

Reference numerals: 10—array substrate; 11—transparent substrate; 12—circuit layer; 121—metal layer; 13—light emitting element; 131—first electrode; 132—second electrode; 14—black glue layer; 141—first part of the black glue layer; 142—second part of the black glue layer; 15—light-through path; 16—light transmitting window; 161—first light transmitting window; 162—second light transmitting window; 163—third light transmitting window; 164—fourth light transmitting window; 171—first pad; 171a—first region; 171b—second region; 171c—third region; 172—second pad; 172a—fourth region; 172b—fifth region; 172c—sixth region; 18—insulating layer; 181—first insulating layer; 19—light transmitting protruding structure; 21—light transmitting cover layer; 22—surface microstructure; 231—first light transmitting opening; 232—second light transmitting opening; 31—first subcircuit; 32—second subcircuit; 33—first power signal line; 34—display panel; X—first direction; Y—second direction; Z—third direction; M₁—first metal layer; M2—second metal layer; M₃—third metal layer; M₄—fourth metal layer; M_{N}—N-th metal layer; M_{N-1—(N-}1)-th metal layer.

### DETAILED DESCRIPTION

The embodiments in the present disclosure will be clearly and thoroughly described with reference to the accompanying drawings. Apparently, the described embodiments are merely part of the embodiments of the present disclosure, but not all of the embodiments. Based on the embodiments in the present disclosure, all other embodiments obtained by a person skilled in the art without making creative efforts are within the scope of protection of the disclosure.

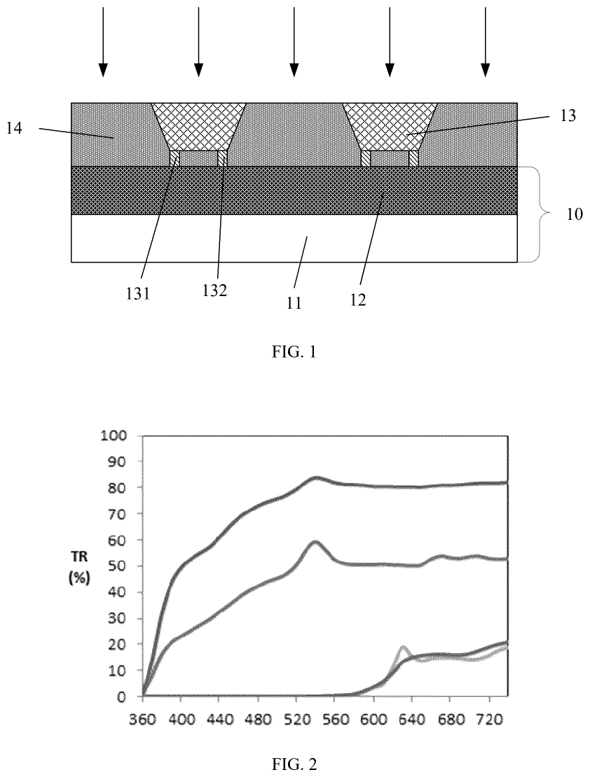

FIG. 1 is a schematic diagram of the principle of photocuring of a conventional display panel, where an array substrate 10 includes a transparent substrate 11 and a circuit layer 12 disposed on the transparent substrate 11, and a plurality of light emitting elements 13 are fixed to the surface of the circuit layer 12. A black glue layer 14 needs to be provided on the surface of the array substrate 10 to prevent light crosstalk between different light emitting elements 13. The bottom of a light emitting element 13 has a first electrode 131 and a second electrode 132, and the light emitting element 13 is electrically connected to a pixel circuit in the circuit layer 12 through the first electrode 131 and the second electrode 132.

In the embodiments of the present disclosure, a light emitting element 13 may be an LED, such as a conventional LED of larger size or a micro LED of smaller size, where the micro LED may be a Mini LED or a Micro LED. The chip size of a conventional LED is generally greater than 200 um. The chip size range of a Mini LED is 50 um to 200 um. The chip size of a Micro LED is less than 100 um, typically 1 um to 10 um. The embodiments of the present disclosure do not limit the sizes of the light emitting elements.

For a conventional display panel, the circuit layer 12 at least includes multiple metal layers for preparing pixel circuits. Since the metal layers cannot transmit UV light used for photocuring, and the light emitting elements 13 have a certain transmittance for UV light, when the black glue layer 14 is photocured, the UV light irradiates the black glue layer 14 from above the array substrate 10 in an irradiation direction as shown by the arrow in FIG. 1, to perform photocuring on the black glue layer 14.

FIG. 2 illustrates the transmittance curves of Micro LED chips for light of different wavelengths. In FIG. 2, the horizontal axis is the wavelength of light and the vertical axis is the transmittance. The two curves on the top are the transmittance curves of two green light Micro LED chips using different green light emitting materials, and the two curves on the bottom are the transmittance curves of two red light Micro LED chips using different red light emitting materials.

From FIG. 2, it can be seen that the transmittance of red light Micro LED chips to UV light is 0, and the transmittance of green light Micro LED chips to UV light is generally less than 20%. FIG. 2 does not show the transmittance curve of blue light Micro LED chips made of blue light emitting materials. The transmittance of blue light Micro LED chips is generally no more than 20%.

Since the transmittance of a LED's light emitting material to UV light is low, the black glue layer under the LED may not obtain sufficient energy, which will cause the black glue layer under the LED to fail to effectively photo-cure.

In order to solve the above problems, an embodiment of the present disclosure provides a display panel, including: an array substrate that includes a transparent substrate, a circuit layer disposed on a surface of the transparent substrate, and a plurality of light emitting elements fixed on the circuit layer, the light emitting elements being electrically connected to the pixel circuits in the circuit layer; and a black glue layer, where the black glue layer includes a first part disposed between the light emitting elements and a second part disposed between a bottom of a light emitting element and the circuit layer. The circuit layer has a preset light-through path, and the light-through path enables the light for photocuring the black glue layer to irradiate from the transparent substrate to the second part of the black glue layer.

In the embodiments of the present disclosure, since a light-through path is provided in the circuit layer, the light-through path may allow the light for photocuring the black glue layer to irradiate from the transparent substrate to the second part of the black glue layer, so that the display panel may be irradiated with UV light from the side facing the transparent substrate, so as to photo-cure the second part of the black glue layer through the light-through path. This allows to effectively photo-cure the black glue layer disposed between the bottoms of the light emitting elements and the array substrate, thereby avoiding the inability to effectively photo-cure that part of the black glue layer that affects the stability and reliability of the display panel.

In order to make the objective, features and advantages of the present disclosure more obvious and easy to understand, the present disclosure is further described in detail hereinafter in conjunction with the accompanying drawings and specific implementation methods.

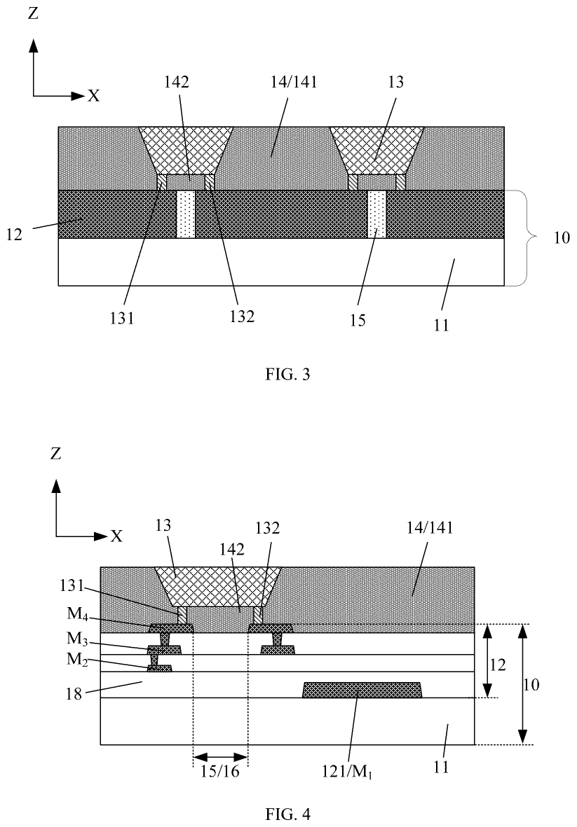

FIG. 3 is a schematic structural diagram of a display panel, in accordance with an embodiment of the present disclosure. The display panel includes: an array substrate 10 that includes a transparent substrate 11, a circuit layer 12 disposed on a surface of the transparent substrate 11, and a plurality of light emitting elements 13 fixed on the circuit layer 12, where a light emitting element 13 is electrically connected to a pixel circuit (not shown in FIG. 3) in the circuit layer 12; and a black glue layer 14 that includes a first part of the black glue layer 141 disposed between the light emitting elements and a second part of the black glue layer 142 disposed between the bottom of a light emitting element 13 and the circuit layer 12. The circuit layer 12 has a preset light-through path 15, where the light-through path 15 may allow the light for photocuring the black glue layer 14 to be irradiated from the transparent substrate 11 to the second part of the black glue layer 142.

Since a light-through path 15 is provided in the circuit layer 12, the light-through path 15 may allow the light for photocuring the black glue layer 14 to irradiate from the transparent substrate 11 to the second part of the black glue layer 142, so that the display panel may be irradiated with UV light from the side facing the transparent substrate 11, so as to photo-cure the second part of the black glue layer 142 through the light-through path 15. This allows to effectively photo-cure the black glue layer 14 disposed between the bottom of the light emitting elements 13 and the array substrate 10, thereby avoiding the failure of effective photocuring of that part of the black glue layer 14 to affect the stability and reliability of the display panel.

In the embodiments of the present disclosure, the transparent substrate 11 may be a hard substrate, such as a glass substrate, a hard plastic plate, etc. The hard substrate may be used to prepare a rigid display panel.

In some embodiments, the transparent substrate 11 may also be a flexible substrate, such as a polyimide substrate, a flexible plastic board, etc. The flexible substrate may be used to prepare a flexible display panel.

FIG. 4 is a schematic diagram of the principle of configuring a light-through path, in accordance with an embodiment of the present disclosure. On the basis of any of the above embodiments, in the configuration shown in FIG. 4, the circuit layer 12 includes a plurality of metal layers 121 stacked in sequence, where at least one metal layer 121 has a light transmitting window 16 for forming a light-through path 15. In a direction perpendicular to a plane where the transparent substrate 11 is located (the direction is parallel to the third direction Z), the light transmitting window 16 in at least one metal layer 121 has an overlapping portion with the second part of the black glue layer 142.

There is an insulating layer 18 between adjacent metal layers 121.

As shown in FIG. 4, a light transmitting window 16 is provided in at least one metal layer 121 in the circuit layer 12, and the light transmitting window 16 in the at least one layer of the metal layer 121 has an overlapping portion with the second part of the black glue layer 142. When UV light irradiates the black glue layer 14 from a side of the transparent substrate 11, the UV light may irradiate the second part of the black glue layer 142 through the light-through path 15 to achieve photocuring of the second part of the black glue layer 142.

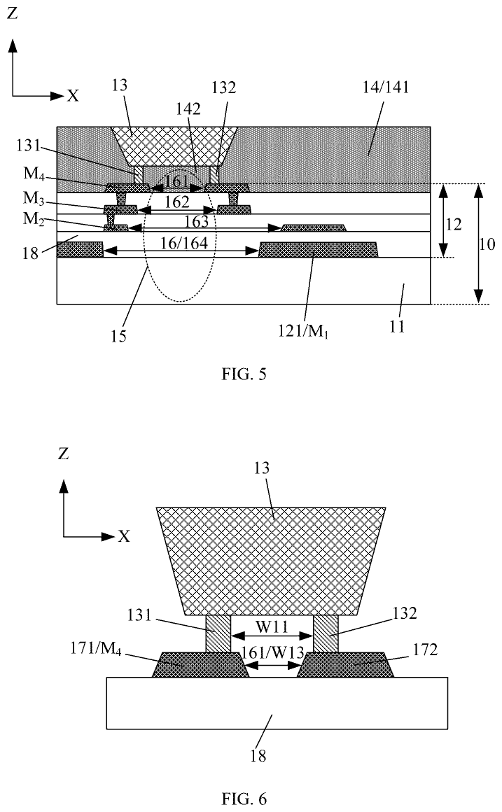

FIG. 5 is a schematic diagram of another principle of configuring a light-through path, in accordance with an embodiment of the present disclosure. Based on the above embodiments, each metal layer 121 in the circuit layer 12 may have a light transmitting window 16, and the light transmitting window 16 in each metal layer 121 is constructed as a part of the light-through path 15.

The circuit layer 12 is configured to include a plurality of metal layers 121 stacked in sequence. In the third direction Z, the plurality of metal layers 121 are sequentially a first metal layer M₁ to an N-th metal layer M_{N}, where N is a positive integer greater than 1. The first metal layer M₁ to the N-th metal layer M_{N} all have a light transmitting window 16. FIG. 5 illustrates a case where N=4 is taken as an example. The fourth metal layer M₄ has a first light transmitting window 161, the third metal layer M₃ has a second light transmitting window 162, the second metal layer M2 has a third light transmitting window 163, and the first metal layer M₁ has a fourth light transmitting window 164. In the embodiments of the present disclosure, the light-through path 15 may be formed based on the light transmitting window(s) 16 configured in the metal layer 121. By adjusting the design positions and parameters of the light transmitting window(s) 16 in the metal layer 121, the extension trajectory and size of the light-through path 15 in the circuit layer 12 may be adjusted, so that when UV light irradiates the black glue layer 14 from a side of the transparent substrate 11, the photocuring effect of the UV light on the second part of the black glue layer 142 is optimized.

As described above, the bottom of a light emitting element 13 is connected to a pixel circuit in the circuit layer 12 via the first electrode 131 and the second electrode 132. In a same light emitting element 13, the first electrode 131 and the second electrode 132 are arranged opposite to each other in the first direction X.

FIG. 6 is a partially enlarged schematic diagram of the display panel shown in FIG. 5 before the black glue layer is laid. Based on the above embodiments, in combination with FIGS. 5 and 6, in some embodiments, in a direction where the transparent substrate 11 points to the light emitting elements 13 (this direction is the third direction Z), the multiple metal layers 121 are sequentially the first metal layer M₁ to the N-th metal layer M_{N}, where N is a positive integer greater than 1.

In the various embodiments disclosed herein, the circuit layer 12 is illustrated as an example in which four metal layers 121 are provided, that is, N=4. Apparently, in the embodiments of the present disclosure, the number of metal layers 121 in the circuit layer 12 may be set according to actual needs, and is not limited to 4 layers, but may be any number of layers. That is, N is not limited to 4, but can be any positive integer greater than 1.

The N-th metal layer M_{N} includes a first pad 171 and a second pad 172, and a first light transmitting window 161 is provided between the first pad 171 and the second pad 172. The bottom of the light emitting element 13 has a first electrode 131 and a second electrode 132, and the first electrode 131 is electrically connected and fixed to the first pad 171, and the second electrode 132 is electrically connected and fixed to the second pad 172. For the same light emitting element 13, there is a first distance W11 between the first electrode 131 and the second electrode 132 that are opposite to each other in the first direction X. The first direction X is parallel to the plane where the transparent substrate 11 is located. In the first direction X, there is a second distance W13 between the first pad 171 and the second pad 172 that connect to the same light emitting element 13, where W11>W13.

In the first direction X, there is a gap between the first electrode 131 and the second electrode 132 to form a first distance W11. With the distance W11, a short circuit between the first electrode 131 and the second electrode 132 may be prevented. The value of W11 may be set according to the bottom size of the light emitting element 13, and the embodiments of the present disclosure do not limit the specific value of W11.

The first light transmitting window 161 between the first pad 171 and the second pad 172 serves as the light transmitting window 16 in the N-th metal layer M_{N}. Setting W11>W13 may prevent W13 from being too large, which causes the first electrode 131 and the second electrode 132 to be unable to be effectively welded and fixed to the first pad 171 and the second pad 172, respectively. This then ensures the reliability and stability of the electrical connection between the bottom electrodes of the light emitting element 13 and the corresponding pads.

When the black glue layer 14 is cured from a side of the transparent substrate 11 by UV light, in order to enable the UV light to irradiate the second part of the black glue layer 142 through the light-through path 15, in the third direction Z, the first light transmitting window 161 is set to at least partially overlap the gap between the first electrode 131 and the second electrode 132.

Optionally, in order to ensure a more uniform illumination effect on the second part of the black glue layer 142, the first light transmitting window 161 is arranged to be vertically relative to the center of the gap between the first electrode 131 and the second electrode 132. That is, the perpendicular bisector of the first light transmitting window 161 perpendicular to the first direction X coincides or approximately coincides with the perpendicular bisector of the first distance W11 perpendicular to the first direction X.

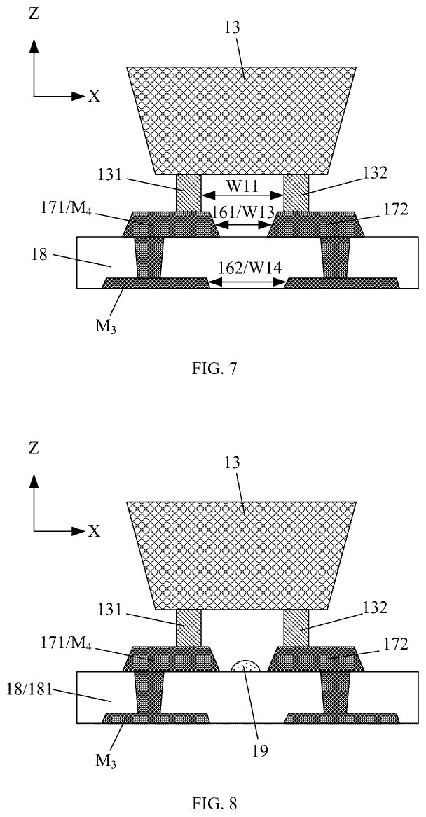

FIG. 7 is another partially enlarged schematic diagram of the display panel shown in FIG. 5 before the black glue layer is laid. In combination with FIGS. 5 and 7, on the basis of the aforementioned embodiments, the (N-1)-th metal layer M_{N-1} is provided with a second light transmitting window 162. In a direction perpendicular to the plane where the transparent substrate 11 is located, the first light transmitting window 161 and the second light transmitting window 162 have an overlapping portion. Based on the overlapping portion of the first light transmitting window 161 and the second light transmitting window 162 in the third direction Z, the light-through path 15 extends from the (N-1)-th metal layer M_{N-1} to the N-th metal layer M_{N}. When UV light is irradiated from a side of the transparent substrate 11, the second part of the black glue layer 142 may be irradiated through the overlapping portion of the first light transmitting window 161 and the second light transmitting window 162, thereby achieving effective photocuring of the second part of the black glue layer 142.

As shown in FIG. 7, in the first direction X, the size of the second light transmitting window 162 is W14. In one embodiment of the present disclosure, W14≠W11.

In some embodiments, W14≠W11. That is, the sizes of the light transmitting windows 16 in the (N-1)-th metal layer M_{N-1} and the N-th metal layer M_{N} in the first direction X may be set differently. On one hand, this is convenient for the layout of circuit patterns in the (N-1)-th metal layer M_{N-1} and the N-th metal layer M_{N}. On the other hand, the light-through path 15 may be configured more flexibly, so as to optimize the photocuring effect of the second part of the black glue layer 142 when the second part of the black glue layer 142 is cured through the light-through path 15.

On the basis of the above embodiments, when W14≠W11, it may be set to W14>W13, as shown in FIG. 7. As mentioned above, in order to ensure the connection effect between the bottom electrodes of a light emitting element 13 and the corresponding pads, it is necessary to set W11>W13. This then causes certain shielding of the light incident on the second part of the black glue layer 142 through the light-through path 15. Setting W14>W13 may enable the (N-1)-th metal layer M_{N-1} under the N-th metal layer M_{N} to have a second light transmitting window 162 with a larger size in the first direction X. This then allows more incident light obtained through the second light transmitting window 162, and thus the proportion of oblique incident light is increased, so as to ensure the photocuring effect of the second part of the black glue layer 142.

In some embodiments, W13>W14. Since various signal lines connected to a pixel circuit, corresponding to a given light emitting element, need to be laid out in the circuit layer 12, the first distance W11 between the two electrodes at the bottom of a light emitting element 13 is a fixed value. After the value of the adapted second distance W13 is set based on the first distance W11 of the light emitting element 13, if the space in the (N-1)-th metal layer M_{N-1} is insufficient to achieve a larger value of W14, it may also be set W13>W14 to facilitate the layout of the signal lines in the (N-1)-th metal layer M_{N-1}.

In the embodiments of the present disclosure, when W13>W14, it may be set to W13>W14≥0.8*W13. When W13>W14, setting W14≥0.8*W13 may avoid W14 being too small and causing too little light to irradiate the second part of the black glue layer 142, which then affects the photocuring effect of the second part of the black glue layer 142.

In some embodiments, W14 and W11 may also be set equal.

In the embodiments of the present disclosure, the relative sizes of the light transmitting windows of each metal layer 121 may be set according to the wiring space in the array substrate 10. The specific ways of determining the sizes of the light transmitting windows 16 in different metal layers 121 in the first direction X may include but are not limited to the methods described in the embodiments of the present disclosure.

FIG. 8 is another partially enlarged schematic diagram of the display panel shown in FIG. 5 before the black glue layer is laid. In combination with FIGS. 5, 6 and 8, based on the above embodiments, a first insulating layer 181 is provided between the N-th metal layer M_{N} and the (N-1)-th metal layer M_{N-1}. At least one light transmitting protruding structure 19 is provided on the surface of the first insulating layer 181 in the area between the first pad 171 and the second pad 172.

Referring to FIGS. 5, 6 and 8, since W11>W13, in the third direction Z, the first solder pad 171 and the second solder pad 172 will have an overlapping portion with the first distance W11, and the overlapping portion will block the second part of the black glue layer 142, thereby affecting the photocuring effect of the second part of the black glue layer 142.

When light is irradiated from a side of the transparent substrate 11, the light transmitting protruding structure 19 may adjust the transmission direction of the light when passing through the first light transmitting window 161, which then expands the light irradiation area to avoid affecting the photocuring effect of the second part of the black glue layer 142 due to the shielding of the second part of the black glue layer 142 by the solder pads.

In the illustrated embodiment in FIG. 8, the light transmitting protruding structure 19 is provided on the surface of the first insulating layer 181 between the first pad 171 and the second pad 172 as an example for illustration. In the embodiments of the present disclosure, one or more light transmitting protruding structures 19 may be provided according to the size of the light transmitting protruding structure 19 and the size of the second distance W13. The way of providing a light transmitting protruding structure(s) 19 is not limited to the configuration shown in FIG. 8.

In some embodiments, the first insulating layer 181 may be set to have a first refractive index n1, and the light transmitting protruding structure 19 may be set to have a second refractive index n2, where n1≠n2. In the embodiment disclosed herein, the design of the refractive index difference between the first insulating layer 181 and the light transmitting protruding structure 19 may be purposed to optimize the transmission path of the light after passing through the first light transmitting window 161, so as to better photo-cure the second part of the black glue layer 142.

In some embodiments, the three-dimensional graphic structure and size of the light transmitting protruding structure 19 may also be optimized to optimize the transmission path of light after passing through the first light transmitting window 161, so as to better photo-cure the second part of the black glue layer 142. The light transmitting protruding structure 19 may be a partial sphere, a partial elliptical sphere, a prism, a cone, an irregular three-dimensional protrusion, etc. The embodiments of the present disclosure do not limit the three-dimensional geometric shape of the light transmitting protruding structure 19.

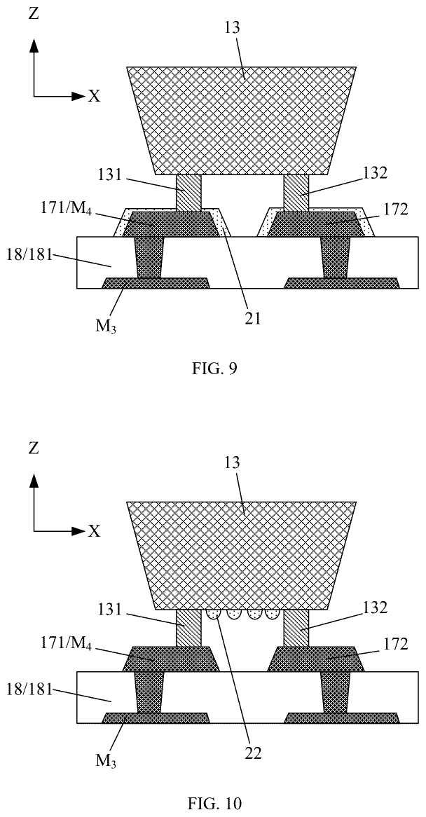

FIG. 9 is another partially enlarged schematic diagram of the display panel shown in FIG. 5 before the black glue layer is laid. In combination with FIGS. 5, 6 and 9, on the basis of the above embodiments, a first insulating layer 181 is provided between the N-th metal layer M_{N} and the (N-1)-th metal layer M_{N-1}. The first insulating layer 181 has a first refractive index n1. For the N-th metal layer M_{N}, at least the side wall of the first pad 171 facing the first light transmitting window 161 and at least the side wall of the second pad 172 facing the first light transmitting window 161 are covered with a light transmitting cover layer 21. The light transmitting cover layer 21 has a third refractive index n3, where n1≠n3.

As mentioned above, the shielding of the second part of the black glue layer 142 by the solder pads will affect the photocuring effect of the second part of the black glue layer 142. In the configuration shown in FIG. 9, by providing a light transmitting cover layer 21 having a different refractive index from the first insulating layer 181, based on the difference in refractive index between the two, the range of light irradiating the second part of the black glue layer 142 may be optimized. When light is photocured from a side of the transparent substrate 11, part of the light may be transmitted through the light transmitting cover layer 21 and then irradiated to the second part of the black glue layer 142. By optimizing the difference in refractive index between the first insulating layer 181 and the light transmitting cover layer 21, the light may more fully irradiate the second part of the black glue layer 142, so as to avoid affecting the photocuring effect of the second part of the black glue layer 142 due to shielding of the second part of the black glue layer 142 by the solder pads.

FIG. 10 is another partially enlarged schematic diagram of the display panel shown in FIG. 5 before the black glue layer is laid. In combination with FIGS. 5, 6 and 10, based on the above embodiments, the bottom of a light emitting element 13 has a surface microstructure 22 at least in the area between the first electrode 131 and the second electrode 132.

As mentioned above, the shielding of the second part of the black glue layer 142 by the solder pads will affect the photocuring effect of the second part of the black glue layer 142. In the configuration shown in FIG. 10, by providing the surface microstructure 22 at the bottom of the light emitting element 13, diffuse reflection of the incident light may be achieved, and the range of light irradiation of the second part of the black glue layer 142 may be optimized. When the light is irradiated from a side of the transparent substrate 11, the light irradiates the surface microstructure 22, and the light transmission direction may be changed through diffuse reflection of the surface microstructure 22, so that the diffusely reflected light may irradiate the second part of the black glue layer 142 shielded by the solder pads. This then avoids affecting the photocuring effect of the second part of the black glue layer 142 due to the shielding of the second part of the black glue layer 142 by the solder pads.

The surface microstructure 22 may be a plurality of micro protrusions formed on the bottom of the light emitting element 13, or a roughened bottom surface of the light emitting element 13. Optionally, the micro protrusions may be a light transmitting glue layer with reflective particles mixed therein.

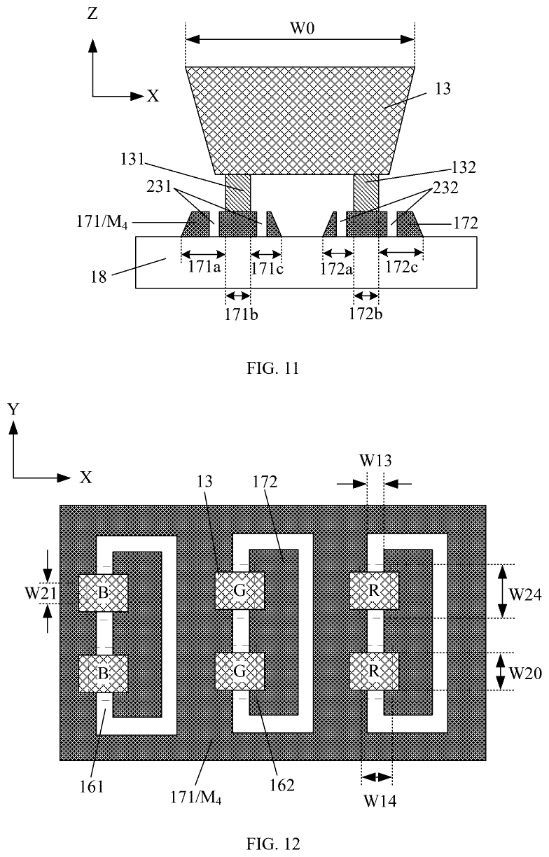

FIG. 11 is another partially enlarged schematic diagram of the display panel shown in FIG. 5 before the black glue layer is laid. In combination with FIGS. 5, 6 and 11, based on the above embodiments, the size of the top of the light emitting element 13 in the first direction X is W10, where W10>W11. The first pad 171 includes a first region 171a, a second region 171b and a third region 171c arranged in sequence along the first direction X, and the first electrode 131 is welded and fixed to the first pad through the second region. At least one of the first region 171a and the third region 171c is provided with a first light transmitting opening 231.

Since W10>W11, the bottom size of the light emitting element 13 is relatively small, and the light emitting element 13 has an inclined side wall. When the light irradiates the black glue layer 14 along the opposite direction of the third direction Z, not only the second part of the black glue layer 142 will be blocked by the light emitting element 13, but the inclined side wall of the light emitting element 13 will also block a portion of the first part of the black glue layer 141.

If a first light transmitting opening 231 is configured in the first region 171a, when light is irradiated along the third direction Z, the black glue layer 14 blocked by the side wall and/or bottom of the light emitting element 13 above the first light transmitting opening 231 in the first region 171a may be more fully photo-cured, thereby improving the photocuring effect of the black glue layer 14.

If a first light transmitting opening 231 is provided in the third region 171c, when light is irradiated along the third direction Z, the black glue layer 14 blocked by the side wall and/or bottom of the light emitting element 13 above the first light transmitting opening 231 in the third region 171c may be more fully cured, thereby improving the photocuring effect of the black glue layer 14.

On the basis of the above embodiments, as shown in FIG. 11, the second pad 172 may include a fourth region 172a, a fifth region 172b and a sixth region 172c sequentially arranged along the first direction X, and the second electrode 132 may be welded and fixed to the second pad 172 through the fifth region 172b. At least one of the fourth region 172a and the sixth region 172c may be provided with a second light transmitting opening 232.

If a second light transmitting opening 232 is configured in the fourth region 172a, when light is irradiated along the third direction Z, the black glue layer 14 blocked by the side wall and/or bottom of the light emitting element 13 above the second light transmitting opening 232 in the fourth region 172a may be more fully cured, thereby improving the photocuring effect of the black glue layer 14.

If a second light transmitting opening 232 is configured in the sixth region 172c, when light is irradiated along the third direction Z, the black glue layer 14 blocked by the side wall and/or bottom of the light emitting element 13 above the second light transmitting opening 232 in the sixth region 172c may be more fully cured, thereby improving the photocuring effect of the black glue layer 14.

In the embodiments of the present disclosure, a light transmitting opening may be provided in at least one of the first region 171a, the third region 171c, the fourth region 172a and the sixth region 172c. The present disclosure is not just limited to the illustrated configuration in FIG. 11, in which the first region 171a, the third region 171c, the fourth region 172a and the sixth region 172c are all provided with a light transmitting opening.

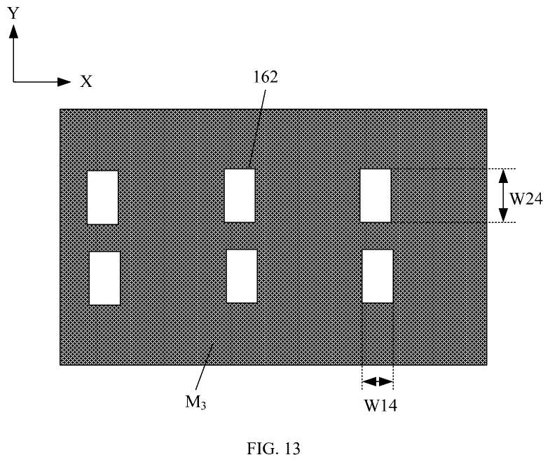

FIG. 12 is a top view of the N-th metal layer in the array substrate, and FIG. 13 is a top view of the (N-1)-th metal layer in the array substrate. FIGS. 12 and 13 also take N=4 as an example for illustration.

The N-th metal layer M_{N} has a plurality of square hollow regions to form a plurality of separated second pads 172. The remaining part of the N-th metal layer M_{N} except the second pads 172 serves as the first pad 171 for all light emitting elements 13. One long side of a square hollow region serves as a first light transmitting window 161.

Referring to FIGS. 12 and 13 and the drawings of the aforementioned embodiments, in the second direction Y, the size of a second light transmitting window 162 is W24. The second direction Y is parallel to the plane where the transparent substrate 11 is located, and is perpendicular to the first direction X. There is a gap between the first electrode 131 and the second electrode 132, and the size of the gap in the second direction Y is W21, where W24>W21.

Setting W24>W21 may make the size of the second light transmitting window 162 in the second direction Y larger than the size of the gap between the two electrodes at the bottom of a light emitting element 13 in the second direction Y, and may make the overlapping portion between the second light transmitting window 162 and the first light transmitting window 161 in the third direction Z completely expose the gap between the two electrodes at the bottom of the light emitting element 13. When the black glue layer 14 is cured along the third direction Z, the second part of the black glue layer 142 may be more fully irradiated to achieve sufficient photocuring of the second part of the black glue layer 142.

Furthermore, W24 may be set larger than the dimension W20 of the top surface of the light emitting element 13 in the second direction Y, so that the black glue layer below the two opposite side walls in the second direction Y of the light emitting element 13 may be fully photo-cured.

The three first light transmitting windows 161 arranged sequentially in the first direction X may be used to respectively weld and fix a red light emitting element R, a green light emitting element G and a blue light emitting element B.

In the embodiments of the present disclosure, the length of the first light transmitting window 161 in the second direction Y is at least greater than W20, so that at least one light emitting element 13 may be welded above the first light transmitting window 161. If there is a faulty light emitting element 13 that cannot emit light in the display panel, the faulty light emitting element 13 may be dug out and then another light emitting element 13 of the same color may be welded and fixed in the original position.

In some embodiments, as shown in FIG. 12, the length of the first light transmitting window 161 in the second direction Y may be set to be greater than 2 times of W20, so that a redundant welding position may be formed above the first light transmitting window 161. If a faulty light emitting element 13, which cannot emit light normally, occurs, another light emitting element 13 with the same light emitting color may be directly welded above the first light transmitting window 161 corresponding to the faulty light emitting element 13, and there is no need to dig out the faulty light emitting element 13.

In the embodiments of the present disclosure, the (N-1)-th metal layer M_{N-1} is provided with a second light transmitting window 162. In a direction perpendicular to the plane where the transparent substrate 11 is located, the (N-1)-th metal layer M_{N-1} at least partially overlaps with the light emitting element 13. In the first direction X, the two opposite sides of the first light transmitting window 161 are located between the two opposite sides of the second light transmitting window 162. As shown in FIG. 12, the two opposite sides of the first light transmitting window 161 in the first direction X are located between the two opposite sides of the second light transmitting window 162 in the first direction X. In this way, in the first direction X, the second light transmitting window 162 may completely expose the first light transmitting window 161 to achieve full photocuring of the second part of the black glue layer 142.

In some embodiments, in a direction perpendicular to the plane where the transparent substrate 11 is located, the number of metal layers 121 in a region of the circuit layer 12 corresponding to the first part of the black glue layer 141 is m1, and the number of metal layers 121 in a region of the circuit layer 12 corresponding to a second part of the black glue layer 142 is m2, where m1 and m2 are both natural numbers, and m1>m2≥0. Taking the configuration shown in FIG. 5 as an example, if the circuit layer 2 has the first metal layer M₁ to the fourth metal layer M4, in the third direction Z, the first metal layer M₁ to the fourth metal layer M4 all have a region corresponding to the first part of the black glue layer 141, that is, m1=4. However, only the first metal layer M₁ has a region corresponding to the second part of the black glue layer 142, that is, m2=1.

In some embodiments, by setting the value of the light transmitting window 16 in each metal layer 121 in the first direction X, the values of m1 and m2 may be adjusted.

Setting m1>m2≥0 may ensure that there is a smaller amount of metal shielding under the second part of the black glue layer 142, so as to improve the photocuring effect of the second part of the black glue layer 142 when the light photo-cures the black glue layer 14 along the third direction Z.

In some embodiments, the N-th metal layer M_{N} may be as shown in FIG. 12. Multiple separate second pads 172 may be formed in the multiple square hollow areas, and the remaining integrated structure of the N-th metal layer M_{N} may be used as the first pad 171 commonly connected to all light emitting elements 13, so that the impedance of the first pad 171 connected to the first electrodes 131 may be reduced, thereby reducing power consumption.

In some embodiments, the N-th metal layer M_{N} may further include a plurality of separated first pads 171 and a plurality of separated second pads 172 and a second power signal line for providing a second power signal VEE to the first pads 171. This configuration may reduce the area ratio of the N-th metal layer M_{N} and reduce its shielding of the black glue layer 14. When photocuring along the third direction Z, the light may not only irradiate the first part of the black glue layer 141, but also irradiate the second part of the black glue layer 142, thereby improving the photocuring effect of the black glue layer 14.

In some embodiments, the (N-1)-th metal layer M_{N-1} may be as shown in FIG. 13. The (N-1)-th metal layer M_{N-1} has a plurality of rectangular hollow areas as the second light transmitting windows 162, and the second light transmitting windows 162 are arranged in a one-to-one correspondence with the light emitting elements 13. At this point, the (N-1)-th metal layer M_{N-1} is an integrated structure. In this configuration, a second light transmitting window 162 may be a rectangle or other opening shape.

Optionally, the (N-1)-th metal layer M_{N-1} may be used to connect the first power signal PAM_VDD to a pixel circuit. The (N-1)-th metal layer M_{N-1} with the graphic structure shown in FIG. 13 may reduce circuit impedance, reduce the voltage drop of the first power signal PAM_VDD, and reduce power consumption.

In some embodiments, the (N-1)-th metal layer M_{N-1} may also include a plurality of first power signal lines, and a first power signal line is configured to connect a pixel circuit to the first power signal PAM_VDD. In this configuration, the gap between adjacent first power signal lines serves as the second light transmitting window 162. This configuration may reduce the area ratio of the (N-1)-th metal layer M_{N-1}, and may reduce its shielding of the black glue layer 14. When photocuring along the third direction Z, the light may not only irradiate the first part of the black glue layer 141, but also irradiate the second part of the black glue layer 142, which may improve the photocuring effect of the black glue layer 14.

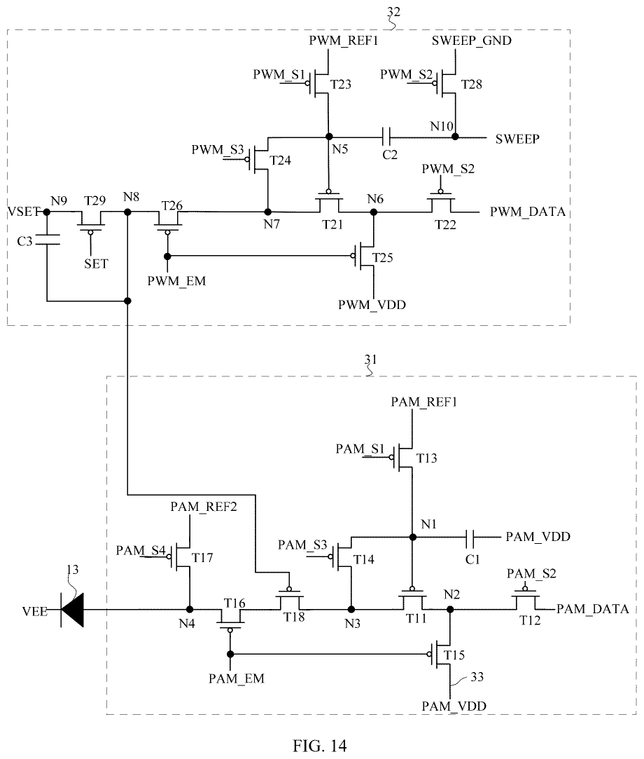

Each light emitting element 13 may be connected to a corresponding pixel circuit, and the structure of the pixel circuit may be as shown in FIG. 14.

FIG. 14 is a schematic structural diagram of a pixel circuit, in accordance with an embodiment of the present disclosure. The pixel circuit in the illustrated embodiment includes a first subcircuit 31 and a second subcircuit 32. The first subcircuit 31 is connected to the light emitting element 13, and the second subcircuit 32 is connected to the first subcircuit 31. The first subcircuit 31 is configured to control the amplitude of the driving current provided to the light emitting element 13, and the second subcircuit 32 is configured to control the pulse width of the driving current provided to the light emitting element 13. The first power signal line 33 provides a first power signal PAM_VDD to the first subcircuit 31. The (N-1)-th metal layer M_{N-1} includes the first power signal lines 33, and the (N-1)-th metal layer M_{N-1} forms a third light transmitting window based on the gap between adjacent first power signal lines.

If the first power signal PAM_VDD is provided through the first power signal line 33, the (N-1)-th metal layer M_{N-1} may be provided with a plurality of first power signal lines 33 intersecting in a grid structure, for connecting the first power signal PAM_VDD to each pixel circuit in the display panel. This method may make the area of the (N-1)-th metal layer M_{N-1} smaller, and may reduce the shielding of the black glue layer 14 by the (N-1)-th metal layer M_{N-1}. When photocuring along the third direction Z, the light may not only irradiate the first part of the black glue layer 141, but also irradiate the second part of the black glue layer 142, which may improve the photocuring effect of the black glue layer 14.

As described above, for a pixel circuit, the first power signal PAM_VDD may also be provided through the (N-1)-th metal layer M_{N-1} of an integrated structure having a hollow area to reduce impedance.

As shown in FIG. 14, the first subcircuit 31 includes the following components.

A first driving transistor T11, where the gate of the first driving transistor T11 is connected to the first node N1, the first electrode is connected to the third node N3, and the second electrode is connected to the second node N2. In the embodiments of the present disclosure, one of the first electrode and the second electrode of each transistor is a source, and the other is a drain.

A first reset transistor T13, where the gate of the first reset transistor T13 receives the first scan signal PAM_S1, the first electrode receives the first reset signal PAM_REF1, and the second electrode is connected to the first node N1.

A first data transistor T12, where the gate of the first data transistor T12 receives the second scan signal PAM_S2, the first electrode is connected to the second node N2, and the second electrode receives the first data signal PAM_DATA.

A first threshold compensation transistor T14, where the gate of the first threshold compensation transistor T14 receives the third scanning signal PAM_S3, the first electrode is connected to the first node N1, and the second electrode is connected to the third node N3.

A first power supply writing transistor T15, where the gate of the first power supply writing transistor receives the first light emitting control signal PAM_EM, the first electrode is connected to the second node N2, and the second electrode receives the first power supply signal PAM_VDD.

A first light emitting control transistor T16, where the gate of the first light emitting control transistor receives the first light emitting control signal PAM_EM, the first electrode is connected to the fourth node N4, and the fourth node N4 is configured to connect the second electrode 132 of the light emitting element 13. The first electrode 131 of the light emitting element 13 receives the second power supply signal VEE.

A second reset transistor T17, where the gate of the second reset transistor T17 receives the third scan signal PAM_S4, the first electrode receives the second reset signal PAM_REF2, and the second electrode is connected to the fourth node N4.

A first control transistor T18, where the gate of the first control transistor T18 is connected to the second subcircuit 32, the first electrode of the first control transistor T18 is connected to the second electrode of the first light emitting control transistor T16, and the second electrode of the first control transistor T18 is connected to the third node N3.

A first capacitor C1, where one plate of the first capacitor C1 is connected to the first node N1, and the other plate receives the first power signal PAM_VDD.

The first power signal PAM_VDD is a DC high level, and the second power signal VEE is a DC low level.

As shown in FIG. 14, the second subcircuit 32 includes the following components.

A second driving transistor T21, where the gate of the second driving transistor T21 is connected to the fifth node N5, the first electrode is connected to the seventh node N7, and the second electrode is connected to the sixth node N6.

A third reset transistor T23, where the gate of the third reset transistor T23 receives the first control signal PWM_S1, the first electrode receives the third reset signal PWM_REF1, and the second electrode is connected to the fifth node N5.

A second data transistor T22, where the gate of the second data transistor T22 receives the second control signal PWM_S2, the first electrode is connected to the sixth node N6, and the second electrode receives the second data signal PWM_DATA.

A second threshold compensation transistor T24, where the gate of the second threshold compensation transistor T24 receives the third control signal PWM_S3, the first electrode is connected to the fifth node N5, and the second electrode is connected to the seventh node N7.

A second power supply writing transistor T25, where the gate of the second power supply writing transistor receives the second light emitting control signal PWM_EM, the first electrode is connected to the sixth node N6, and the second electrode receives the third power supply signal PWM_VDD. The third power supply signal PWM_VDD may be a DC high level.

A second light emitting control transistor T26, where the gate of the second light emitting control transistor receives the second light emitting control signal PWM_EM, the first electrode is connected to the eighth node N8, and the second electrode is connected to the seventh node N7.

A second capacitor C2, where one plate of the second capacitor C2 is connected to the fifth node N5, and the other plate of the second capacitor C2 is connected to the tenth node N10, and the tenth node N10 receives the sweep signal SWEEP.

A second control transistor T28, where the gate of the second control transistor T28 receives the second control signal PWM_S2, the first electrode receives the ground signal SWEEP_GND, and the second electrode is connected to the tenth node N10.

A third control transistor T29, where the gate of the third control transistor T29 receives the fourth control signal SET, the first electrode is connected to the ninth node N9, and the second electrode is connected to the eighth node N8. A third capacitor C3 is connected between the eighth node N8 and the ninth node N9, and the ninth node N9 receives the fifth control signal VSET.

The second subcircuit 32 is connected to the first subcircuit 31 via an eighth node N8. As shown in FIG. 14, the eighth node N8 is connected to the gate of the first control transistor T18.

In the embodiments, the implementation of the first subcircuit 31 and the second subcircuit 32 is not limited to that shown in FIG. 14.

In some embodiments, the second subcircuit 32 may be without the third capacitor C3 and the third control transistor T29, and may be directly connected to the first subcircuit 31 via a capacitor at the eighth node N8.

In some embodiments, the first subcircuit 31 and the second subcircuit 32 may also be provided with bias transistors connected to the first electrodes of the respective data transistors.

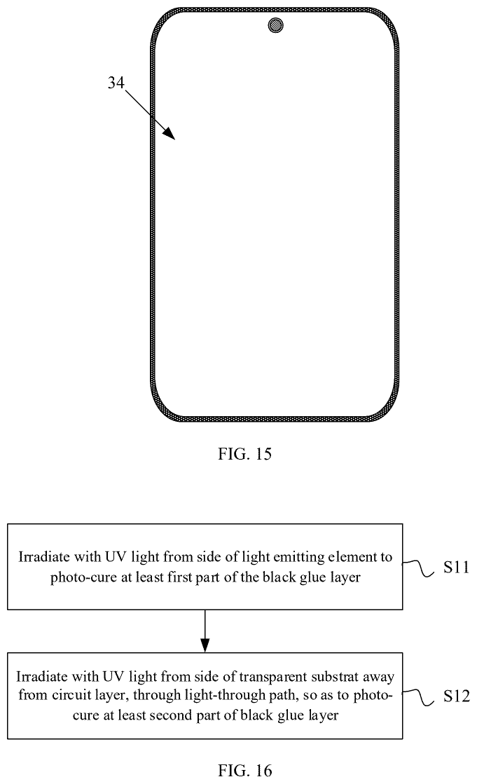

Based on the display panel provided in the above embodiments, another embodiment of the present disclosure further provides an electronic device, which may be as shown in FIG. 15.

FIG. 15 is a schematic structural diagram of an electronic device, in accordance with an embodiment of the present disclosure. The electronic device includes a display panel 34 provided in any of the above embodiments.

The electronic devices include but are not limited to electronic devices with display functions such as mobile phones, tablet computers, laptops, and smart wearable devices.

The electronic device provided in the embodiments of the present disclosure adopts the display panel 34 provided in any of the above embodiments, which may improve the photocuring effect of the black glue layer 14 in the display panel 34, so as to improve the reliability and stability of the display panel.

Based on the above embodiments, another embodiment of the present disclosure further provides a method for photocuring a display panel. The method may be used for photocuring the black glue layer 14 in the display panel provided in any of the above embodiments, as shown in FIG. 16.

FIG. 16 is a flow chart of a display panel photocuring method, in accordance with an embodiment of the present disclosure. The method includes the following steps.
Step S11: Irradiate with UV light from a side of the light emitting element 13 to photo-cure at least the first part 141 of the black glue layer 14.

In Step S11, light is irradiated from the top of the light emitting element 13 in the opposite direction of the third direction Z to photo-cure the black glue layer 14. The photocuring process may mainly photo-cure the first part of the black glue layer 141.
Step S12: Irradiate with UV light from a side of the transparent substrate 11 away from the circuit layer 12, through the light-through path 15, so as to photo-cure at least the second part 142 of the black glue layer 14.

In Step S12, light is irradiated from the bottom of the light emitting element 13 along the third direction Z to photo-cure the black glue layer 14. During the photocuring process, since the light emitting element 13 does not block the light, the transmittance of the UV light may reach more than 70% through the light-through path 15.

In the embodiments of the present disclosure, the light-through path 15 designed for the display panel provided in the above embodiments may enable the display panel to perform photocuring on at least the second part of the black glue layer 142 along the third direction Z, thereby improving the photocuring effect of the second part of the black glue layer 142.

In Step S12, the method of irradiating the transparent substrate with UV light from the side away from the circuit layer may include: irradiating the transparent substrate 11 with UV light in dotted areas, where the irradiated areas of the UV light are the areas corresponding to the light emitting elements 13. Since the first part of the black glue layer 141 may be sufficiently photocured in Step S11, the second part of the black glue layer 142 may be photocured in Step S12 by localized illumination corresponding to the light emitting elements 13 one by one. Since a large area of illumination is not required, the light energy loss may be reduced.

In some embodiments, the method of irradiating the transparent substrate 11 with UV light from the side away from the circuit layer may include: irradiating the transparent substrate 11 with planar UV light, and the irradiated areas of the UV light include the areas corresponding to the light emitting elements 13 and the areas corresponding to the gaps between the light emitting elements 13. This method may utilize the light transmitting areas of the metal layer(s) 121 corresponding to the first part of the black glue layer 141 to further perform photocuring on the first part of the black glue layer 141.

In some embodiments, the order of Step S11 and Step S12 may be adjusted. Step S11 may be executed first, and then Step S12, or Step S12 may be executed first, and then Step S11, which is not limited in the present disclosure.

From the above description, it can be seen that for the electronic device, display panel and photocuring method provided by the technical solution of the present disclosure, since a light-through path is set in the circuit layer, the light-through path may make the light for photocuring the black glue layer irradiate from the transparent substrate to the second part of the black glue layer, so that the display panel may be irradiated with UV light from the side facing the transparent substrate, so as to photo-cure the second part of the black glue layer through the light-through path. This allows to effectively photo-cure the black glue layer located between the bottom of a light emitting element and the array substrate, thereby avoiding the failure of effectively photocuring that part of the black glue layer to affect the stability and reliability of the display panel.

In the specification of the present disclosure, each embodiment is described in a progressive, parallel, or progressive and parallel manner, and each embodiment focuses on the differences from other embodiments. The same or similar parts between the embodiments may refer to each other. The implementation methods provided in the embodiments of the disclosure may be combined with each other if there is no conflict.

It should be noted that in the description of the present disclosure, the description of the drawings and embodiments is illustrative rather than restrictive. The same reference numerals throughout the embodiments of the specification identify the same structure. In addition, for the sake of understanding and ease of description, the drawings may exaggerate the thickness of some layers, films, panels, regions, etc. It is also understood that when an element such as a layer, film, region, or substrate is referred to as “on” another element, the element may be directly on the other element or there may be an intermediate element. In addition, “on” refers to positioning an element on or below another element, but does not essentially refer to positioning on the upper side of another element according to the direction of gravity.

The terms “upper”, “lower”, “top”, “bottom”, “inner”, “outer”, and the like indicate positions or positional relationships based on the positions or positional relationships shown in the drawings, and are merely for the convenience of describing the present disclosure and simplifying the description, rather than indicating or implying that the device or element referred to must have a specific orientation, be constructed and operated in a specific orientation, and therefore cannot be understood as limiting the present disclosure. When a component is considered to be “connected” to another component, it may be directly connected to the other component or there may be an intermediately arranged component at the same time.

It should also be noted that, in the present disclosure, relational terms such as first and second, etc., are merely used to distinguish one entity or operation from another entity or operation, and do not necessarily require or imply any such actual relationship or order between these entities or operations. Moreover, the terms “comprises”, “comprising” or any other variants thereof are intended to cover non-exclusive inclusion, so that an article or device including a series of elements includes not only those elements, but also other elements not explicitly listed, or also includes elements inherent to such article or device. In the absence of further restrictions, the elements defined by the sentence “comprising a . . . ” do not exclude the existence of other identical elements in the article or device including the above elements.

The above description of the disclosed embodiments enables those skilled in the art to implement or use the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments shown herein, but will conform to the widest scope consistent with the principles and novel features disclosed herein.

What is claimed is:

1. A display panel, comprising:
an array substrate, wherein the array substrate includes a transparent substrate, a circuit layer disposed on a surface of the transparent substrate, and a plurality of light emitting elements fixed on the circuit layer, the light emitting elements being electrically connected to pixel circuits in the circuit layer; and
a black glue layer, wherein the black glue layer includes a first part disposed between the light emitting elements and a second part disposed between a bottom of a light emitting element and the circuit layer,
wherein the circuit layer has a preset light-through path, and the light-through path enables light for photocuring the black glue layer to be irradiated from the transparent substrate to the second part of the black glue layer.

2. The display panel according to claim 1, wherein:
the circuit layer includes a plurality of metal layers stacked in sequence;
among the plurality of metal layers, at least one of the metal layers has a light transmitting window for forming the light-through path; and
in a direction perpendicular to a plane where the transparent substrate is located, the light transmitting window in the at least one of the metal layers has an overlapping portion with the second part of the black glue layer.

3. The display panel according to claim 2, wherein each of the metal layers has the light transmitting window, and the light transmitting window in each of the metal layers is constructed as the light-through path.

4. The display panel according to claim 2, wherein:
in a direction from the transparent substrate to the light emitting element, the plurality of metal layers are sequentially from a first metal layer to an N-th metal layer, wherein N is a positive integer greater than 1;
the N-th metal layer includes a first pad and a second pad, and a first light transmitting window is provided between the first pad and the second pad;
a bottom of the light emitting element includes a first electrode and a second electrode, the first electrode is electrically connected and fixed to the first pad, and the second electrode is electrically connected and fixed to the second pad;
for the same light emitting element, there is a first distance W11 between the first electrode and the second electrode opposite to each other in a first direction, and the first direction is parallel to the plane where the transparent substrate is located; and
in the first direction, there is a second distance W13 between the first pad and the second pad connecting the same light emitting element, wherein W11□W13.

5. The display panel according to claim 4, wherein an (N-1)-th metal layer is provided with a second light transmitting window, and in the direction perpendicular to the plane where the transparent substrate is located, the first light transmitting window and the second light transmitting window have an overlapping portion.

6. The display panel according to claim 5, wherein, in the first direction, a size of the second light transmitting window is W14, wherein W14≠W13.

7. The display panel according to claim 6, wherein W14>W13.

8. The display panel according to claim 6, wherein W13>W14≥0.8*W13.

9. The display panel according to claim 4, wherein a first insulating layer is provided between the N-th metal layer and an (N-1)-th metal layer, and at least one light transmitting protruding structure is provided on a surface of the first insulating layer in a region between the first pad and the second pad.

10. The display panel according to claim 9, wherein the first insulating layer has a first refractive index n1, and the light transmitting protruding structure has a second refractive index n2, wherein n1≠n2.

11. The display panel according to claim 4, wherein:
a first insulating layer is provided between the N-th metal layer and an (N-1)-th metal layer, and the first insulating layer has a first refractive index n1; and
for the N-th metal layer, at least a side wall of the first pad facing the first light transmitting window and at least a side wall of the second pad facing the first light transmitting window are covered with a light transmitting cover layer, and the light transmitting cover layer has a third refractive index n3, wherein n1≠n3.

12. The display panel according to claim 4, wherein:
a size of a top of the light emitting element in the first direction is W10, wherein W10>W11; and
the first pad includes a first region, a second region and a third region arranged in sequence along the first direction, the first electrode is welded and fixed to the first pad through the second region, and at least one of the first region and the third region is provided with a first light transmitting opening.

13. The display panel according to claim 4, wherein:
a size of a top of the light emitting element in the first direction is W10, wherein W10>W11; and
the second pad includes a fourth region, a fifth region and a sixth region sequentially arranged along the first direction, the second electrode is welded and fixed to the second pad through the fifth region, and at least one of the fourth region and the sixth region is provided with a second light transmitting opening.

14. The display panel according to claim 5, wherein:
in a second direction, a size of the second light transmitting window is W24, wherein the second direction is parallel to the plane where the transparent substrate is located and is perpendicular to the first direction; and
there is a gap between the first electrode and the second electrode, and a size of the gap in the second direction is W21, wherein W24>W21.

15. The display panel according to claim 4, wherein:
an (N-1)-th metal layer is provided with a second light transmitting window, and in the direction perpendicular to the plane where the transparent substrate is located, the (N-1)-th metal layer and the light emitting element at least partially overlap; and
in the first direction, two opposite sides of the first light transmitting window are located between two opposite sides of the second light transmitting window.

16. The display panel according to claim 2, wherein, in the direction perpendicular to the plane where the transparent substrate is located, a quantity of metal layers in a region of the circuit layer corresponding to the first part of the black glue layer is m1, and a quantity of metal layers in a region of the circuit layer corresponding to the second part of the black glue layer is m2, wherein m1 and m2 are both natural numbers, and m1>m2≥0.

17. The display panel according to claim 4, wherein:
a pixel circuit includes a first subcircuit and a second subcircuit, wherein the first subcircuit is connected to the light emitting element, and the second subcircuit is connected to the first subcircuit;
the first subcircuit is configured to control an amplitude of a driving current provided to the light emitting element, and the second subcircuit is configured to control a pulse width of the driving current provided to the light emitting element;
a first power signal line provides a first power signal to the first subcircuit; and
an (N-1)-th metal layer includes the first power signal line, and the (N-1)-th metal layer forms a third light transmitting window based on a gap between adjacent first power signal lines.

18. An electronic device, comprising a display panel, wherein the display panel includes:
an array substrate, wherein the array substrate includes a transparent substrate, a circuit layer disposed on a surface of the transparent substrate, and a plurality of light emitting elements fixed on the circuit layer, the light emitting elements being electrically connected to pixel circuits in the circuit layer; and
a black glue layer, wherein the black glue layer includes a first part disposed between the light emitting elements and a second part disposed between a bottom of a light emitting element and the circuit layer,
wherein the circuit layer has a preset light-through path, and the light-through path enables light for photocuring the black glue layer to be irradiated from the transparent substrate to the second part of the black glue layer.

19. A method for photocuring the display panel according to claim 1, the method comprising:
irradiating with UV light from a side of the light emitting element to photo-cure at least the first part of the black glue layer; and
irradiating with UV light from a side of the transparent substrate away from the circuit layer, through the light-through path, so as to photo-cure at least the second part of the black glue layer.

20. The method according to claim 19, wherein irradiating with UV light from a side of the transparent substrate away from the circuit layer comprises:
irradiating the transparent substrate with UV light in dotted areas, wherein UV light irradiation areas correspond to the light emitting elements; or
irradiating the transparent substrate with planar UV light, wherein UV light irradiation areas include areas corresponding to the light emitting elements and areas corresponding to gaps between the light emitting elements.
